(19) United States
(12) Patent Application Publication
(10) Pub. No.: US 2016/0066463 A1
(43) Pub. Date: Mar. 3, 2016

(54) CURVED ELECTRONIC DEVICE

(71) Applicant: InnoLux Corporation, Miao-Li County (TW)

(72) Inventors: Yi-Xin YANG, Miao-Li County (TW); Cheng-Hsiung LIU, Miao-Li County (TW); Fang-Iy WU, Miao-Li County (TW); Cheng-Hsu CHOU, Miao-Li County (TW)

(21) Appl. No.: 14/825,422

(22) Filed: Aug. 13, 2015

(30) Foreign Application Priority Data
Aug. 27, 2014 (TW) 103129474

(51) Int. Cl. H05K 7/02

(52) U.S. Cl. CPC H05K 7/02

(57) ABSTRACT

A curved electronic device includes a shaping layer having a first curved surface and a second curved surface opposite to the first curved surface, and an electronic element conformably disposed over the first curved surface of the shaping layer, wherein the shaping layer comprises radiation-curable materials or thermal-curable materials.

### CROSS REFERENCE TO RELATED APPLICATION

This Application claims priority of Taiwan Patent Application No. 103129474, filed on Aug. 27, 2014, the entirety of which is incorporated by reference herein.

### BACKGROUND OF THE INVENTION

1. Field of the Invention

The embodiments relate to electronic devices, and in particular to curved electronic devices.

2. Description of the Related Art

As technology advances, technologies used in display devices develop continuously. Flat panel display (FPD) devices those are light, thin, short, and small have replaced the traditional heavy cathode-ray tube (CRT) monitors.

However, there are a variety of flat panel display devices. Common flat panel display devices include, for example, liquid-crystal display (LCD) devices, organic light-emitting diode (OLED) display devices, and light-emitting diode (LED) display devices.

Since the design of consumer electronic products has changed from a focus on functionality to artistic development, such as with novel and fashionable topics thereof, consumers may not only focus on function, but on the aesthetics of the product, which is major factor affecting consumer choice. Furthermore, due to the flat panel displays being thin and flat, flat panel displays have been arranged on a non-planar surface of the electronics devices of the consumer electronic products.

Therefore, there is a need for a curved electronic device for application in a wide range of products with a non-planar surface.

### BRIEF SUMMARY OF THE INVENTION

An exemplary curved electronic device comprises a shaping layer having a first curved surface and a second curved surface opposite to the first curved surface, and an electronic element conformably disposed over the first curved surface of the shaping layer, wherein the shaping layer comprises radiation-curable materials or thermal-curable materials.

In one embodiment, the above curved electronic device further comprises a protection plate disposed over the second curved surface of the shaping layer.

In another embodiment, the first and second surfaces of the above curved electronic device have a convex shape, a concave shape or a wave-like shape.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic flowchart showing a method for fabricating a curved electronic device according to an embodiment;

FIG. 2 is a schematic flowchart showing a method for fabricating a curved electronic device according to another embodiment;

FIG. 3 is a schematic flowchart showing a method for fabricating a curved electronic device according to yet another embodiment;

FIG. 4 is a schematic flowchart showing a method for fabricating a curved electronic device according to another embodiment;

FIG. 5 is a schematic cross section showing a curved electronic device according to an embodiment;

FIG. 6 is a schematic cross section showing a curved electronic device according to another embodiment;

FIG. 7 is a schematic cross section showing a curved electronic device according to yet another embodiment;

FIG. 8 is a schematic cross section showing a curved electronic device according to another embodiment;

FIG. 9 is a schematic cross section showing a curved electronic device according to yet another embodiment;

FIG. 10 is a schematic cross section showing a curved electronic device according to another embodiment;

FIG. 11 is a schematic cross section showing a curved electronic device according to yet another embodiment;

FIG. 12 is a schematic cross section showing a curved electronic device according to another embodiment;

FIG. 13 is a schematic cross section showing a curved electronic device according to yet another embodiment;

FIG. 14 is a schematic cross section showing a curved electronic device according to another embodiment;

FIG. 15 is a schematic cross section showing a curved electronic device according to yet another embodiment;

FIG. 16 is a schematic cross section showing a curved electronic device according to another embodiment;

FIG. 17 is a schematic cross section taken along line 17-17 in the curved electronic device shown in FIG. 15; and

FIG. 18 is a schematic cross section taken along line 18-18 in the curved electronic device shown in FIG. 16.

### DETAILED DESCRIPTION OF THE INVENTION

The following description is of the embodiments of carrying out the invention. This description is made for the purpose of illustrating the general principles of the invention and should not be taken in a limiting sense. The scope of the invention is best determined by reference to the appended claims.

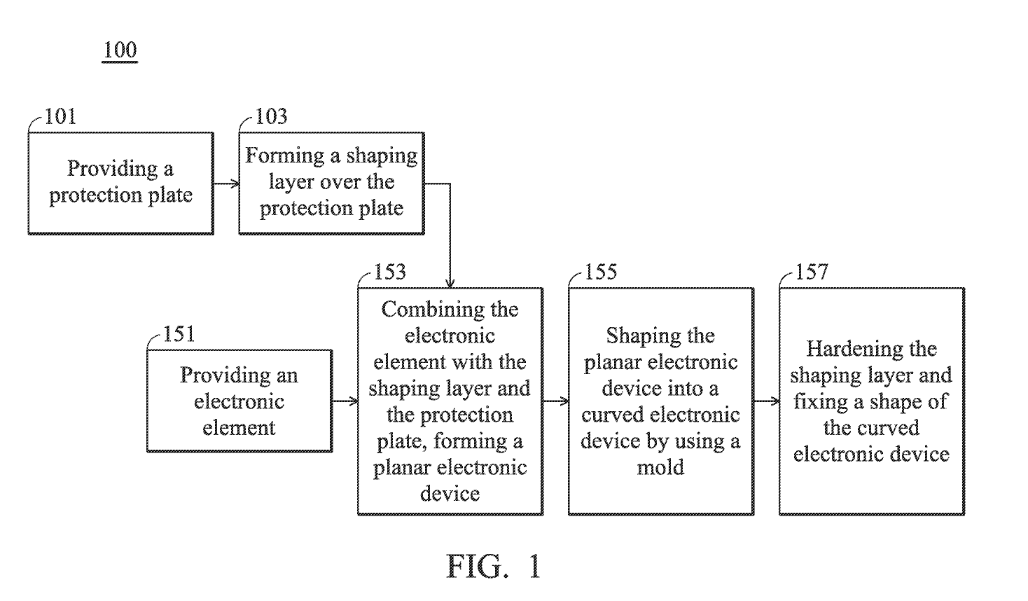

FIG. 1 illustrates a flowchart of an exemplary method 100 for fabricating a curved electronic device.

As shown in FIG. 1, the method 100 begins at steps 101 and 151. In step 101, a protection plate is provided. In one embodiment, the protection plate may comprise materials such as glass, plastic, metal or a combination thereof, and may be light-transmitting or opaque, thereby providing functions such as being mechanically supporting, light-shielding, light-transmitting or light-reflective. In step 151, an electronic element, for example a light-emitting element or a display element, is provided, and the electronic element comprises a substrate therein. Next, step 103 is performed. In step 103, a shaping layer is formed over a surface of the protection plate. In one embodiment, the shaping layer can be a dry film or a wet film, and may have a thickness between 0.5 μm and 0.5 cm. Therefore, the shaping layer can be formed over the surface of the protection plate by methods such as film adhesion or coating. In one embodiment, the shaping layer may comprise curable materials, such as radiation-curable materials or thermal-curable materials. The radiation-curable materials can be, for example, acrylic-based radiation-curable materials, epoxy-based radiation-curable materials, silicon-based radiation-curable materials, or combinations thereof, and the thermal-curable materials can be, for example, acrylic-based thermal-curable materials, epoxy-based thermal-curable materials, silicon-based thermal-curable materials, or combinations thereof. Next, step 153 is performed to combine the electronic element with a surface of the shaping layer without the protection plate, thereby forming a planar electronic device. Next, step 155 is performed and the planar electronic device is shaped into a curved electronic device having two-dimensional (2D) curved surfaces or three dimensional (3D) curved surfaces by use of a mold having two-dimensional (2D) or three dimensional (3D) curved surfaces. Next, step 157 is performed to harden the shaping layer and fix the shape of the substrate of the electronic element in the curved electronic device by performing an energy processing step such as an ultra-violet (UV) illumination process or a heating process. Therefore, the formed curved electronic device may have a curved surface of non-planar configuration, for example two-dimensional (2D) curved surfaces or three dimensional (3D) curved surfaces. In one embodiment, the two-dimensional (2D) curved surfaces can be the curved surfaces of a convex shape, a concave shape or a wave-like shape.

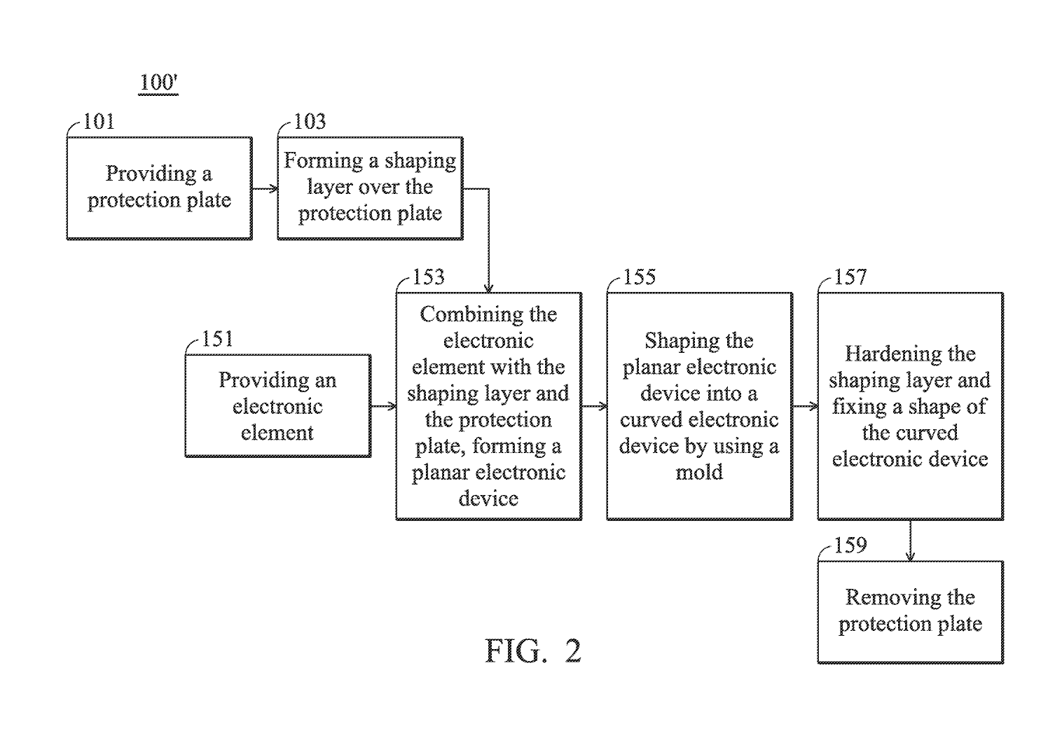

FIG. 2 illustrates a flowchart of another exemplary method 100′ for fabricating a curved electronic device. The method 100′ is obtained by modifying the method 100 illustrated in FIG. 1, and steps in FIG. 2 that are the same as those in the method 100 are labeled with the same reference numbers. Herein, in the method 100′, step 159 is further performed after step 157 to remove the protection plate, thereby leaving a curved electronic device without a protection plate and reducing the thickness of the formed curved electronic device.

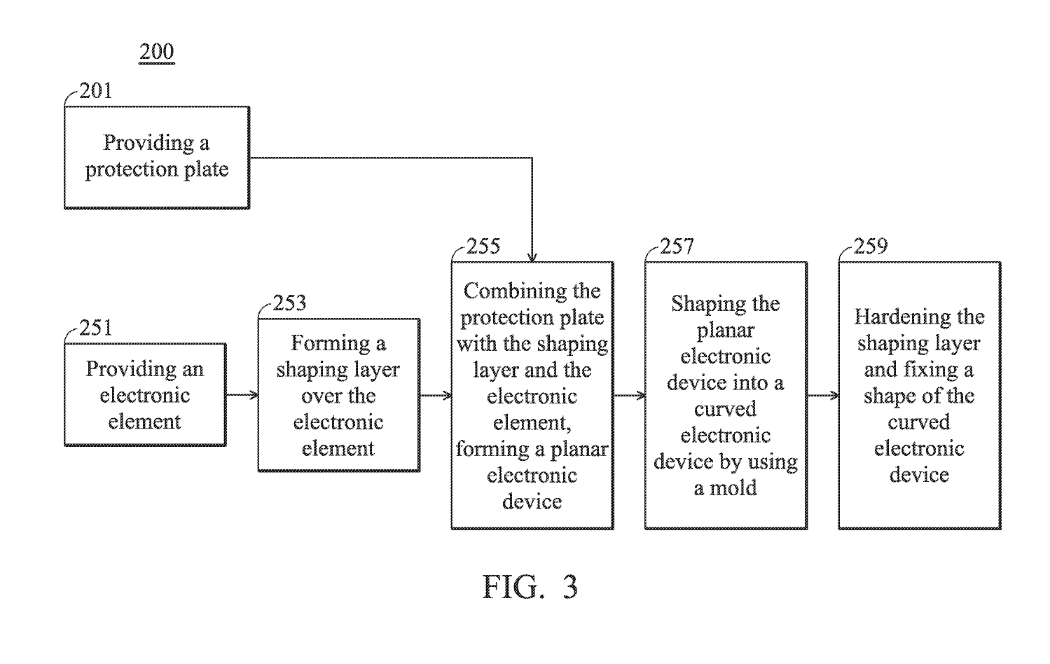

FIG. 3 illustrates a flowchart of yet another exemplary method 200 for fabricating a curved electronic device.

As shown in FIG. 3, the method 200 begins at steps 201 and 251. In step 201, a protection plate is provided. In one embodiment, the protection plate may comprise materials such as glass, plastic, metal or a combination thereof, and may be light-transmitting or opaque, thereby providing functions such as being mechanically supporting, light-shielding, light-transmitting or light-reflective. In the step 251, an electronic element, for example a light-emitting element or a display element, is provided, and the electronic element comprises a substrate therein. Next, step 253 is performed. In step 253, a shaping layer is formed over a surface of the electronic element. In one embodiment, the shaping layer can be a dry film or a wet film, and may have a thickness between 0.5 μm and 0.5 cm. Therefore, the shaping layer can be formed over the surface of the electronic element by methods such as film adhesion or coating. In one embodiment, the shaping layer may comprise curable materials, such as radiation-curable materials or thermal-curable materials. Next, the step 255 is performed to combine the protection plate with a surface of the shaping layer without the protection plate, thereby forming a planar electronic device. Next, step 257 is performed and the planar electronic device is shaped into a curved electronic device having two-dimensional (2D) curved surfaces or three dimensional (3D) curved surfaces by use of a mold having two-dimensional (2D) or three dimensional (3D) curved surfaces. Next, step 259 is performed to harden the shaping layer and fix a shape of the substrate of the electronic element in the curved electronic device by performing an energy processing step such as a ultra-violet (UV) illumination process or a heating process. Therefore, the formed curved electronic device may have a curved surface of non-planar configuration, for example two-dimensional (2D) curved surfaces or three dimensional (3D) curved surfaces. In one embodiment, the two-dimensional (2D) curved surfaces can be curved surfaces of a convex shape, a concave shape or a wave-like shape.

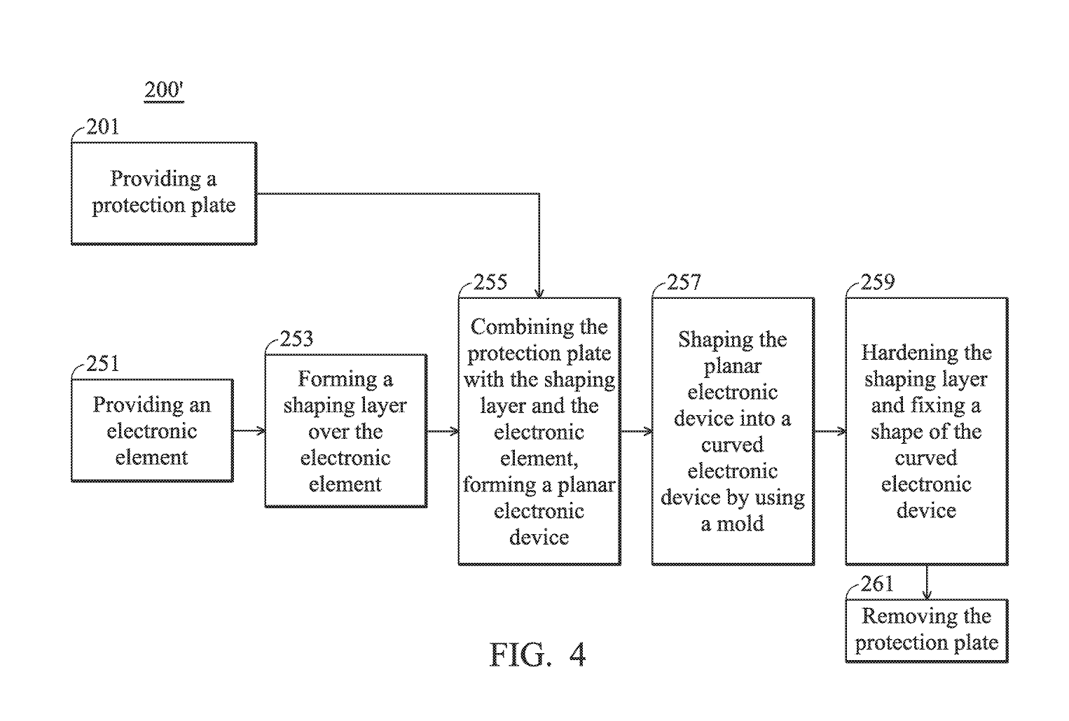

FIG. 4 illustrates a flowchart of another exemplary method 200′ for fabricating a curved electronic device. The method 200′ is obtained by modifying the method 200 illustrated in FIG. 3, and steps in FIG. 4 that are the same as those in the method 200 are labeled with the same reference numbers. Herein, in the method 200′, step 261 is further performed after step 259 to remove the protection plate, thereby leaving a curved electronic device without a protection plate and reducing the thickness of the formed curved electronic device.

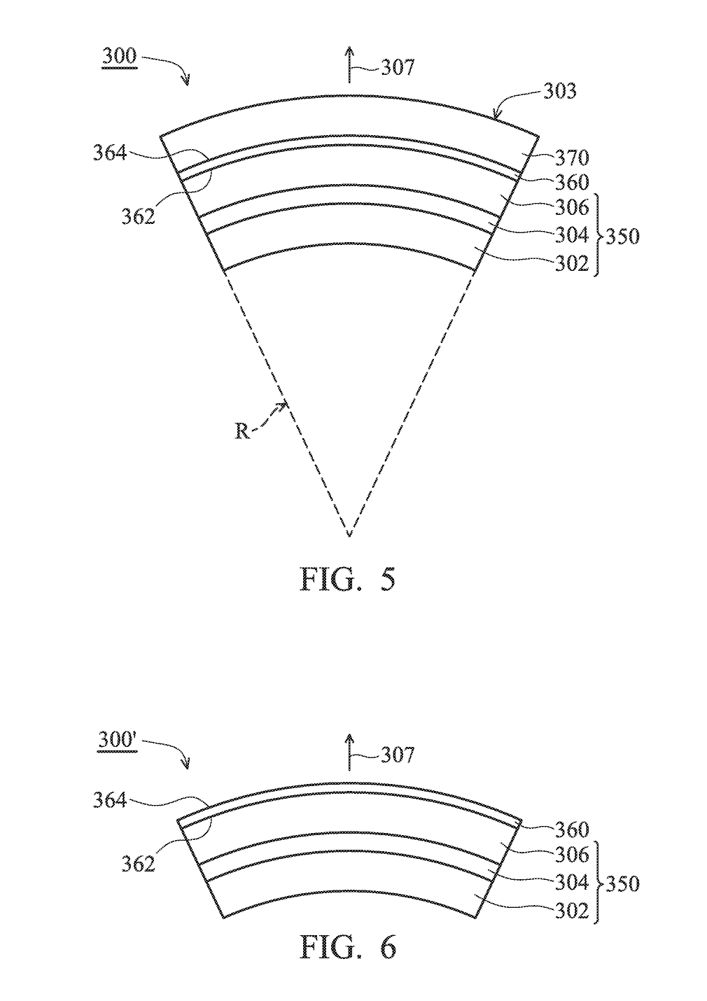

FIG. 5 illustrates a schematic cross section of an exemplary curved electronic device 300. As shown in FIG. 5, the curved electronic device 300 is a convex-shaped curved electronic device, comprising an electronic element 350, a shaping layer 360, and a protection plate 370. The electronic element 350 comprises an electronic unit 304 and a capping layer 306 sequentially stacked over a substrate 302. The shaping layer 360 is formed over a convex-shaped surface of the electronic element 350, such that the electronic element 350 may have a better curvature for forming the curved electronic device. The shaping layer 360 comprises opposite first curved surface 362 and second curved surface 364. Herein, the first curved surface 362 and the second curved surface 364 are convex-shaped surfaces with respect to the electronic element 350. However, the first curved surface 362 is an outer convex-shaped surface and the second curved surface 364 is an inner concave-shaped surface with respect to the shaping layer 360. The capping layer 306 of the electronic element 350 is connected with the first curved surface 362, and the protection plate 370 is connected with the second curved surface 364, and the shaping layer 360 fixes a shape of the substrate 302 in the electronic element 350. In this embodiment, fabrication of the curved electronic device 300 can be achieved by the method 100 illustrated in FIG. 1 or the method 200 illustrated in FIG. 3, such that the curved electronic device 300 may still comprise the protection plate 370, which provides functions such as being mechanical supporting, wear-resisting, scratch-resisting, light-shielding, light-transmitting or light-reflective. In one embodiment, the electronic element 350 can be a light emitting element such as a light-emitting diode (LED) element, and the electronic unit therein can be a light-emitting diode unit. In another embodiment, the electronic element 350 can be a display element such as an organic light-emitting diode (OLED) display element or a liquid crystal display (LCD) element, and the electronic unit 304 therein can be an OLED display unit or a LCD unit. The surface of the protection plate 370 not contacting the capping layer 306 is a light-emitting surface 303, and a direction away from the light emitting surface 303 is a light-emitting direction 307.

FIG. 6 illustrates a schematic cross section of another exemplary curved electronic device 300′. The curved electronic device 300′ shown in FIG. 6 is obtained by modifying the curved electronic device 300 shown in FIG. 5, and the same components in FIG. 6 are labeled with the same reference numbers. In this embodiment, fabrication of the curved electronic device 300′ can be achieved by the fabrication method 100′ shown in FIG. 2 or the fabrication method 200′ shown in FIG. 4, such that the curved electronic device 300′ does not comprise the protection plate 370, and the second curved surface 364 functions as the light-emitting surface, and a direction away from the light emitting surface 303 is the light emitting direction 307. Therefore, a thickness of the curved electronic device 300′ can be reduced, and other components therein are the same as those of the curved electronic device 300 shown in FIG. 5 and are not described here in detail.

In the curved electronic devices 300 and 300′ shown in FIGS. 5-6, the first curved surface 362 and the second curved surface 364 may have a radius of curvature R of about 1-2000 mm, or 10-2000 mm, such that the substrate 302 also has a radius of curvature R of about 1-2000 mm, or 10-2000 mm.

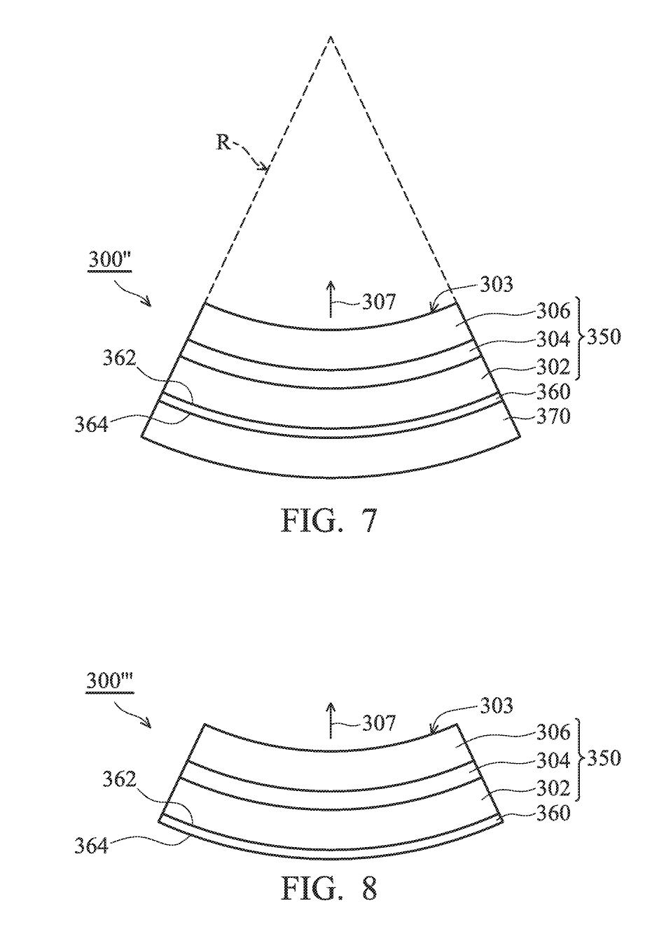

FIG. 7 illustrates a schematic cross section of yet another exemplary curved electronic device 300″. The curved electronic device 300″ shown in FIG. 7 is obtained by modifying the curved electronic device 300 shown in FIG. 5, and the same components in FIG. 7 are labeled with the same reference numbers. In this embodiment, fabrication of the curved electronic device 300″ can be achieved by the fabrication method 100 shown in FIG. 1 or the fabrication method 200 shown in FIG. 3, such that the curved electronic device 300″ comprises the protection plate 370. In addition, unlike the curved electronic device 300 shown in FIG. 5, the curved electronic device 300″ shown in FIG. 7 is a concave-shaped curved electronic device 300″, and the substrate 302 of the electronic element 350 is disposed over the first curved surface 362 of the shaping layer 360, and a surface of the capping layer 306 not contacting the light-emitting unit 304 is a light-emitting surface 303, and a direction away from the light-emitting surface 303 is a light-emitting direction 307. Herein, the first curved surface 362 is an inner concave surface with respect to the shaping layer 360 and the second curved surface 364 is an outer convex surface with respect to the shaping layer 360. The shaping layer 360 is formed over a convex-shaped surface of the electronic element 350 such that the electronic element may have a better degree of bending to form the curved electronic device. Other components in the curved electronic device 300″ are the same as those in the curved electronic device 300 shown by FIG. 5 and are not described here in detail.

FIG. 8 illustrates a schematic cross section of another exemplary curved electronic device 300″. The curved electronic device 300′″ shown in FIG. 8 is obtained by modifying the curved electronic device 300′ shown in FIG. 6, and the same components in FIG. 8 are labeled with the same reference numbers. In this embodiment, fabrication of the curved electronic device 300′″ can be achieved by the fabrication method 100′ shown in FIG. 2 or the fabrication method 200′ shown in FIG. 4, such that the curved electronic device 300′″ does not comprise the protection plate 370, and a thickness of the curved electronic device 300′″ can be thus reduced. Unlike the curved electronic device 300′ shown in FIG. 6, the substrate 302 in the electronic element 350 in the curved electronic device 300′″ shown in FIG. 8 is disposed over the first curved surface 362 of the shaping layer 360, and a surface of the capping layer 306 not contacting the light-emitting unit 304 is the light-emitting surface 303, and a direction away from the light-emitting surface 303 is the light-emitting direction 307. Other components in the curved electronic device 300′″ are the same as those in the curved electronic device 300′ shown by FIG. 6 and are not described here in detail.

In the curved electronic devices 300″ and 300′″ shown in FIGS. 7-8, the first curved surface 362 and the second curved surface 364 may have a radius of curvature R of about 1-2000 mm, or 10-2000 mm, such that the capping layer 306 also has a radius of curvature R of about 1-2000 mm, or 10-2000 mm.

As shown above, by using the methods 100, 100′, 200, and 200′ described above, a plurality of curved electronic devices 300, 300′, 300″ and 300′″ shown in FIGS. 5-8 of various configurations can be thus fabricated. In addition, a plurality of curved electronic devices used in various applications can be also obtained by changing the electronic element 350 in the curved electronic devices 300, 300′, 300″ and 300′″.

FIG. 9 illustrates a schematic cross section of another exemplary curved electronic device 400. The curved electronic device 400 shown in FIG. 9 can be obtained by modifying the curved electronic device 300 shown in FIG. 5, and the same components in FIG. 9 are labeled with the same reference numbers. In this embodiment, fabrication of the curved electronic device 400 can be achieved by the fabrication method 100 shown in FIG. 1 or the fabrication method 200 shown in FIG. 3, such that the curved electronic device 400 may comprise the protection plate 370. In addition, unlike the curved electronic device 300 shown in FIG. 5, in the curved electronic device 400 shown in FIG. 9, a light-emitting element 450 is used to replace the electronic element 350 of the curved electronic device 300 in FIG. 5. Herein, the light-emitting element 450 can be, for example, a light-emitting diode (LED) element, which comprises a substrate 402, a light-emitting diode unit 404, and a capping layer 406 sequentially disposed. Herein, the light-emitting diode unit 404 is illustrated as a single film layer, but it may comprise an n-type semiconductor layer, a multiple quantum well (MQW) layer, and a p-type semiconductor layer stacked over the substrate 402. The substrate 402 may comprise materials such as glass, plastic, metal or combinations thereof, and the capping layer 406 may comprise materials such as glass, plastic, metal or combinations thereof. Herein, the protection plate 370 and the shaping layer 360 are the same with those described above.

In addition, in other embodiments, the electronic element 450 in FIG. 9 can also be used to replace the electronic element 350 of the curved electronic devices 300′, 300″, and 300′″ shown in FIGS. 6-8, thereby forming curved electronic devices similar with those shown in FIGS. 6-8.

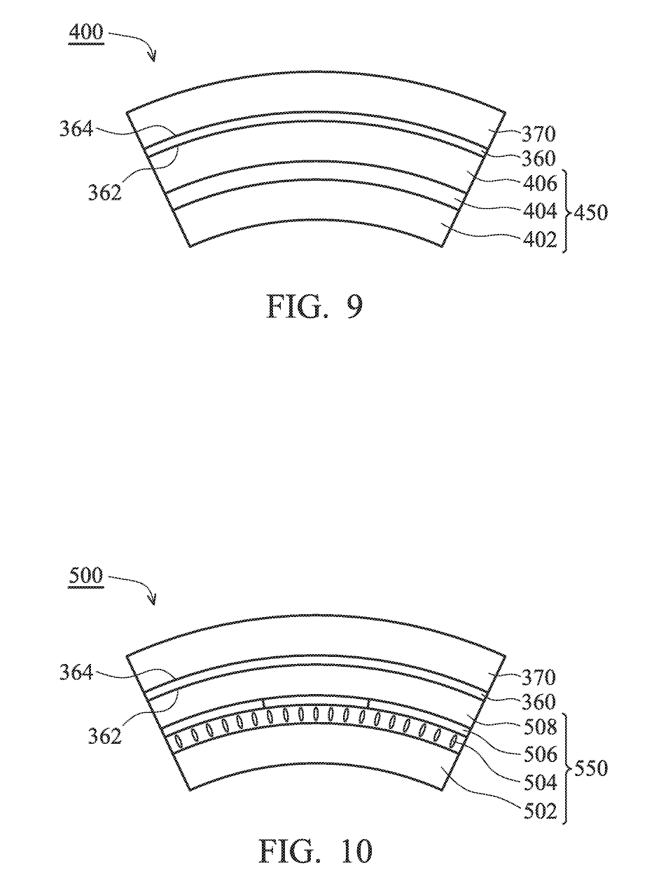

FIG. 10 illustrates a schematic cross section of another exemplary curved electronic device 500. The curved electronic device 500 shown in FIG. 10 can be obtained by modifying the curved electronic device 300 shown in FIG. 5, and the same components in FIG. 10 are labeled with the same reference numbers. In this embodiment, fabrication of the curved electronic device 500 can be achieved by the fabrication method 100 shown in FIG. 1 or the fabrication method 200 shown in FIG. 3, such that the curved electronic device 400 may comprise the protection plate 370. In addition, unlike the curved electronic device 300 shown in FIG. 5, in the curved electronic device 500 shown in FIG. 10, a liquid-crystal display (LCD) element 550 is used to replace the electronic element 350 of the curved electronic device 300 in FIG. 5. Herein, the LCD element 550 may comprise a substrate 502, a liquid-crystal layer 504, a color filter layer 506, and a capping layer 508. Herein, other components such as thin-film transistors and an electrode layer (not shown) can be further disposed over the substrate 502. The substrate 502 may comprise materials such as glass, plastic, metal or combinations thereof, and the color filter layer 504 may comprise materials of nematic liquid crystals or cholesteric liquid crystals, and the color filter layer 506 may comprise an array of patterns of red, blue and green colors, and the capping layer 508 may comprise materials such as glass, plastic, metal or combinations thereof. Herein, the protection plate 370 and the shaping layer 360 are the same as those described above.

In addition, in other embodiments, the electronic element 550 in FIG. 10 can also be used to replace the electronic element 350 of the curved electronic devices 300′, 300″, and 300′″ shown in FIGS. 6-8, thereby forming curved electronic devices similar with those shown in FIGS. 6-8.

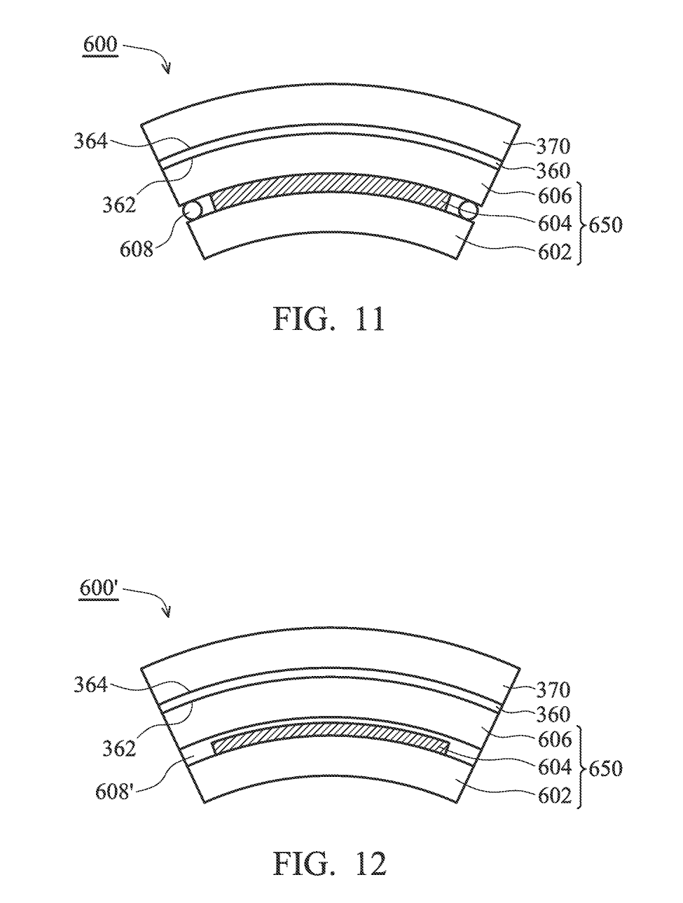

FIG. 11 illustrates a schematic cross section of another exemplary curved electronic device 600. The curved electronic device 600 shown in FIG. 11 can be obtained by modifying the curved electronic device 300 shown in FIG. 5, and the same components in FIG. 11 are labeled with the same reference numbers. In this embodiment, fabrication of the curved electronic device 600 can be achieved by the fabrication method 100 shown in FIG. 1 or the fabrication method 200 shown in FIG. 3, such that the curved electronic device 600 may comprise the protection plate 370. In addition, unlike the curved electronic device 300 shown in FIG. 5, in the curved electronic device 600 shown in FIG. 11, an organic light-emitting diode (OLED) display element 650 is used to replace the electronic element 350 of the curved electronic device 300 in FIG. 5. Herein, the OLED display element 650 may comprise a substrate 602, an organic light-emitting diode (OLED) layer 604 disposed over the substrate 602, a capping layer 606, and a sealing frame 608 disposed between the substrate 602 and the capping layer 604 for surrounding the OLED layer 604. Herein, the substrate 602 may comprise materials such as glass, plastic, metal or combinations thereof, the OLED layer 604 may comprise array patterns of red, blue and green colors, and the capping layer 606 may comprise materials such as glass, plastic, metal or combinations thereof, and the sealing frame 608 may comprise materials such as radiation-curable materials, thermal-curable materials, or pressure-sensitive adhesive materials. Herein, the protection plate 370 and the shaping layer 360 are the same with those described above.

In addition, in other embodiments, the OLED display element 650 in FIG. 11 can also be used to replace the electronic element 350 of the curved electronic devices 300′, 300″, and 300′″ shown in FIGS. 6-8, thereby forming curved electronic devices similar with those shown in FIGS. 6-8.

FIG. 12 illustrates a schematic cross section of another exemplary curved electronic device 600′. The curved electronic device 600′ shown in FIG. 12 is obtained by modifying the curved electronic device 600 shown in FIG. 11, and the same components in FIG. 12 are labeled with the same reference numbers. Unlike the curved electronic device 600 shown in FIG. 11, in the curved electronic device 600′ shown in FIG. 12, the OLED layer 604 is entirely covered with an encapsulating layer 608′.

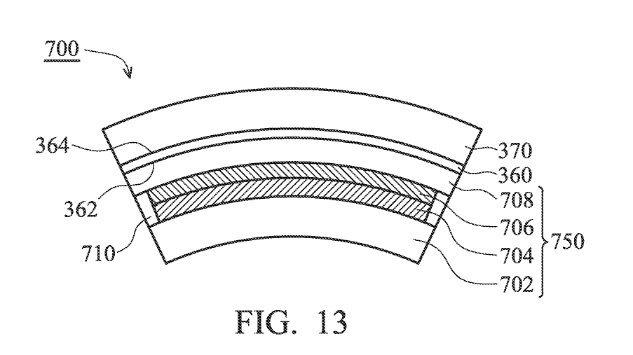

FIG. 13 illustrates a schematic cross section of another exemplary curved electronic device 700. The curved electronic device 700 shown in FIG. 13 is obtained by modifying the curved electronic device 300 shown in FIG. 5, and the same components in FIG. 13 are labeled with the same reference numbers. In this embodiment, fabrication of the curved electronic device 700 can be achieved by the fabrication method 100 shown in FIG. 1 or the fabrication method 200 shown in FIG. 3, such that the curved electronic device 700 may comprise the protection plate 370. In addition, unlike the curved electronic device 300 shown in FIG. 5, in the curved electronic device 700 shown in FIG. 13, an organic light-emitting diode (OLED) display element 750 is used to replace the electronic element 350 of the curved electronic device 300 in FIG. 5. Herein, the OLED display element 550 may comprise a substrate 702, an organic light-emitting diode (OLED) layer 704 disposed over the substrate 702, a color filter layer 706, a capping layer 708, and a sealing frame 710 disposed between the substrate 702 and the capping layer 708 for surrounding the OLED layer 704. Herein, the substrate 702 may comprise materials such as glass, plastic, metal or combinations thereof, and the OLED layer 704 may comprise a stack of material layers (not shown) for emitting white light, comprising, for example, an anode layer, a hole injection layer, a hole transferring layer, a light-emitting layer, an electron transferring layer, an electron injection layer. The color filter layer 706 may comprise an array of patterns of red, blue and green colors, and the capping layer 708 may comprise materials such as glass, plastic, metal or combinations thereof. The sealing frame 710 may comprise materials such as radiation-curable materials, thermal-curable materials, or pressure-sensitive adhesive materials. Herein, the protection plate 370 and the shaping layer 360 are the same with those described above.

In addition, in other embodiments, the OLED display element 750 in FIG. 13 can also be used to replace the electronic element 350 of the curved electronic devices 300′, 300″, and 300′″ shown in FIGS. 6-8, thereby forming curved electronic devices similar with those shown in FIGS. 6-8.

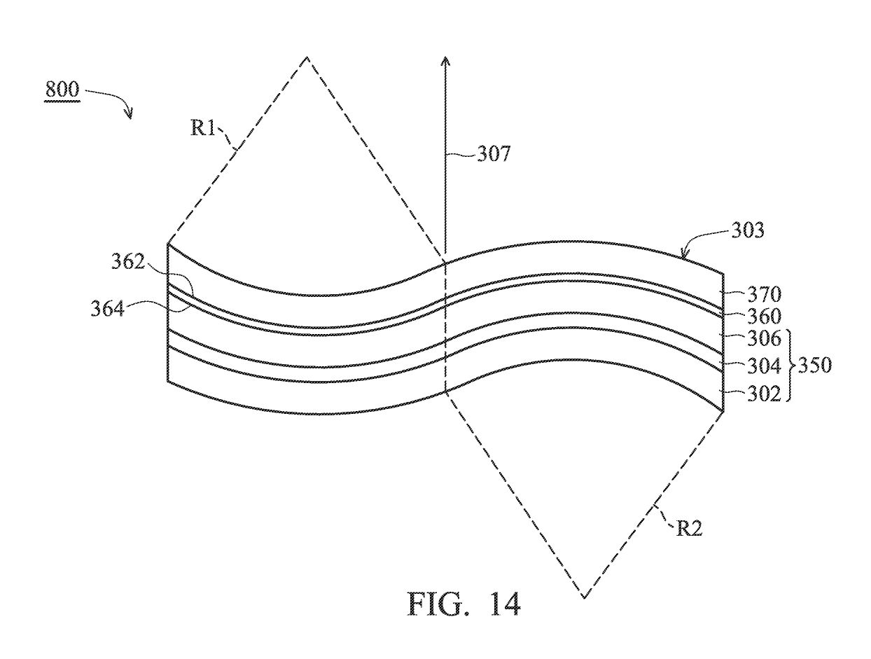

In the above curved electronic devices, the surface of each film layer can be two-dimensional curved surfaces of convex shape or concave shape. However, in other embodiments, the curved electronic devices may have a wave-shaped curved configuration as shown in FIG. 14 by using a mold having a two-dimensional curved surface of another pattern during the fabrication thereof.

FIG. 14 illustrates a schematic cross section of yet another exemplary curved electronic device 800. The curved electronic device 800 shown in FIG. 14 is a wave-shaped curved electronic device. The curved electronic device 800 may comprise an electronic element 350, a shaping layer 360 and a protection plate 370. The electronic element 350 comprises an electronic unit 304 and a capping layer 306 sequentially stacked over the substrate 302. The shaping layer 360 may comprise a first curved surface 362 and an opposite second curved surface 364. Herein, the first curved surface 362 and the second curved surface 364 are wave-shaped surfaces opposite to the electronic element 350. The capping layer 306 of the electronic element 350 is connected to the first curved surface 362, and the protection plate 370 is connected to the second curved surface 364. In this embodiment, fabrication of the curved electronic device 800 can be achieved by the fabrication method 100 shown in FIG. 1 or the fabrication method 200 shown in FIG. 3, such that the curved electronic device 300 may still comprise the protection plate 370, which provides functions such as mechanical supporting, wear-resistant, scratch-resistant, light-shielding, light-transmission or light-reflection. In one embodiment, the electronic element 350 can be a light emitting element such as a light-emitting diode (LED) element, and the electronic unit therein can be a light-emitting diode unit. In another embodiment, the electronic element 350 can be a display element such as an organic light-emitting diode (OLED) display element or a liquid crystal display (LCD) element, and the electronic unit 304 therein can be an OLED display unit or a LCD unit. The surface of the protection plate 370 not in contacting with the capping layer 306 is a light-emitting surface 303, and a direction away from the light emitting surface 303 is a light-emitting direction 307. In the curved electronic device 800 shown in FIG. 14, since the first curved surface 362 and the second surface 364 are wave-shaped surfaces, such that these surfaces may have a plurality of radii of curvatures illustrated as R1 and R2 here, respectively between 1-2000 mm, or 10-2000 mm. Therefore, the substrate 302 also has a plurality of radium of curvature. Film layers in the curved electronic device 800 shown in FIG. 14 are not limited by those shown in FIG. 5, and may have other configurations.

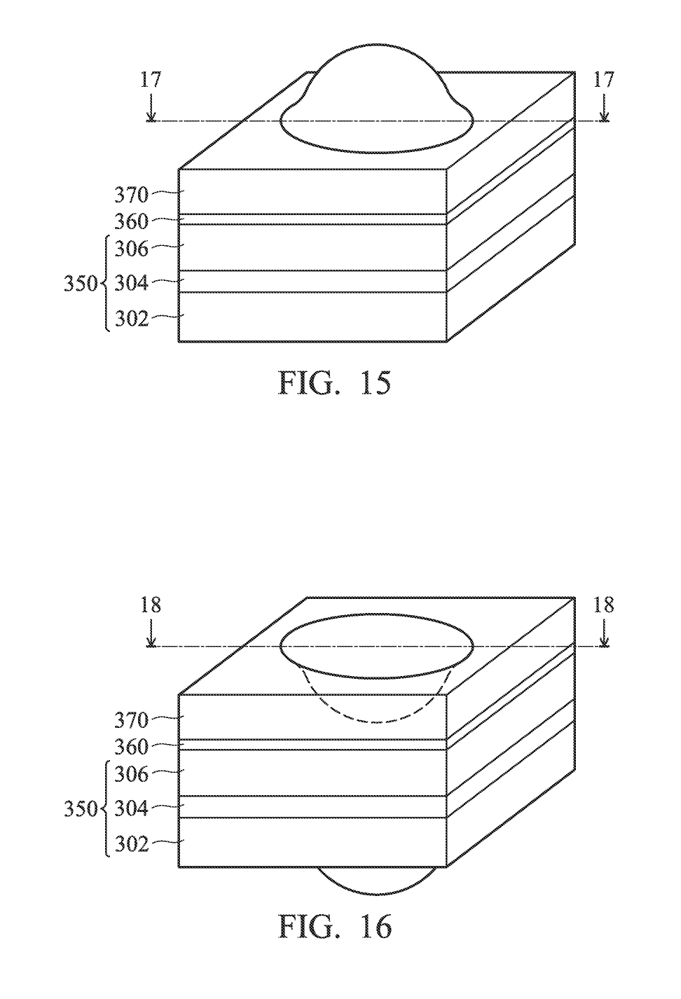

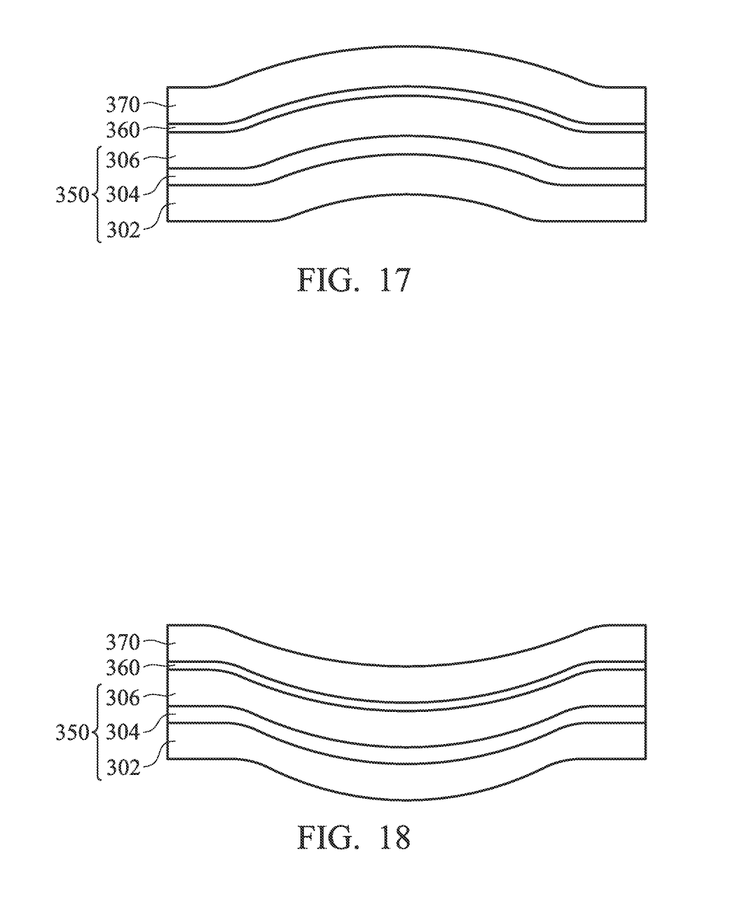

However, in other embodiments, the above curved electronic devices can be fabricated by a mold having a three-dimensional curved surface of other shapes, thereby forming the curved electronic devices having a dome shape surface as shown in FIG. 15 and the curved electronic device having a bowl shape surface as shown in FIG. 16. Film layers in the curved electronic device shown in FIGS. 15-16 are illustrated as those shown in FIG. 5 but are not limited thereto and may have other configurations. FIG. 17 shows a schematic cross section taken along line 17-17 of the curved electronic device shown in FIG. 15, and FIG. 18 shows a schematic cross section taken along line 18-18 of the curved electronic device shown in FIG. 16. As shown in FIGS. 17-18, all the components in the curved electronic devices corresponding to the dome shape curved surface or the bowl shape curved surface are bended to form the dome shape curved surface or the bowl shape curved surface.

In addition, the curved electronic devices shown in FIGS. 6-13 may have a curved surface of the wave shape, dome shape, and bowl shape shown in FIGS. 14-16, and are not limited by those shown in FIGS. 6-13.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A curved electronic device, comprising
a shaping layer, having a first curved surface and a second curved surface opposite to the first curved surface; and
an electronic element conformably disposed over the first curved surface of the shaping layer, wherein the shaping layer comprises radiation-curable materials or thermal-curable materials.

2. The curved electronic device as claimed in claim 1, further comprising a protection plate disposed over the second curved surface of the shaping layer.

3. The curved electronic device as claimed in claim 1, wherein the first curved surface has a convex shape, a concave shape or a wave-like shape.

4. The curved electronic device as claimed in claim 1, wherein the second curved surface has a convex shape, a concave shape or a wave-like shape.

5. The curved electronic device as claimed in claim 1, wherein the electronic element is a display element.

6. The curved electronic device as claimed in claim 5, wherein the display element is an organic light-emitting diode display element or a liquid crystal display element.

7. The curved electronic device as claimed in claim 1, wherein the first curved surface and the second curved surface have at least one radius of curvature.

8. The curved electronic device as claimed in claim 7, wherein the radius of curvature of the first curved surface is about 1-2000 mm.

9. The curved electronic device as claimed in claim 7, wherein the radius of curvature of the first curved surface is about 10-2000 mm.

10. The curved electronic device as claimed in claim 7, wherein the radius of curvature of the second curved surface is about 1-2000 mm.

11. The curved electronic device as claimed in claim 7, wherein the radius of curvature of the second curved surface is about 10-2000 mm.

12. The curved electronic device as claimed in claim 1, wherein the shaping layer comprises a material of selected from the group consisting of acrylic-based radiation-curable materials, epoxy-based radiation-curable materials, silicon-based radiation-curable materials, and combinations thereof.

13. The curved electronic device as claimed in claim 1, wherein the shaping layer comprises a material of selected from the group consisting of acrylic-based thermal-curable materials, epoxy-based thermal-curable materials, silicon-based thermal-curable materials, and combinations thereof.

14. The curved electronic device as claimed in claim 1, wherein the shaping layer has a thickness of about 0.5 μm-0.5 cm.
